(19) United States
(12) Patent Application Publication
(10) Pub. No.: US 2015/0168450 A1
(43) Pub. Date: Jun. 18, 2015

(54) Coaxial Impedance-Matched Test Socket

(71) Applicants: Tim WOODEN, Santa Clara, CA (US); Sergey Ivankov, Santa Clara, CA (US)

(72) Inventors: Tim WOODEN, Santa Clara, CA (US); Sergey Ivankov, Santa Clara, CA (US)

(21) Appl. No.: 14/181,943

(22) Filed: Feb. 17, 2014

Related U.S. Application Data
(60) Provisional application No. 61/917,196, filed on Dec. 17, 2013.

(51) Int. Cl. G01R 1/04; G01R 31/28

(52) U.S. Cl. CPC G01R 1/0466; G01R 31/2886; G01R 31/2884

(57) ABSTRACT

A coaxial impedance-matched test socket having a socket body with a structure similar to a system of redistributed coaxial cable inserts, where the core of each insert comprises a pogo pin, a metal layer that surrounds the pogo pin functions as a shielding element of the core, and an air gap and an insulation filling between the pogo pin and the shielding metal part function as an isolator. For higher system efficiency in matching impedances between the pogo pins and the test object, the insulation fillings, which are placed between the outer surfaces of the control pogo pins and the inner surfaces of the metal layers, are made from a dielectric material of low dielectric permittivity. By selecting specific dielectric materials with the required dielectric parameters, full matching can be provided.

### FIELD OF THE INVENTION

The present invention relates to devices for testing electrical and electronic devices with external lead contacts, such as the bumps on integrated circuit (IC) chips, in particular, to final high-speed test (FHST) sockets. More specifically, the invention provides an FHST socket that eliminates crosstalk, creates impedance-controlled signals of different values on the same socket, and at the same manufactures the mentioned sockets less expensively than traditional CNC (computer numerical control) machining by using printed circuit board technology.

### BACKGROUND OF THE INVENTION

In general, when the process of manufacturing a semiconductor chip, such as an IC, or the like, is completed, electrical performance, quality, etc., of the semiconductor chip are tested. When a semiconductor device is to be tested, a test socket is placed between the lead contacts of the IC and the terminals of the measurement device.

Current flows from the test terminals of the test device into the lead terminals of the semiconductor chip through the test socket, and signals from the lead terminals are analyzed to determine whether the semiconductor chip is abnormal.

The increased working frequency of IC devices creates a challenge to FHST testing because traditional test sockets made out of insulative material, such as plastics and ceramics, do not perform well. FHST test sockets made of insulative materials with high or low dielectric permittivity cannot prevent contactor crosstalk because the wavelength becomes comparable to the length of the contactors whereby the contactors behave as antennas and propagate radio frequency.

There are many types of test sockets, some of which are aimed at eliminating crosstalk and controlling impedance.

U.S. Pat. No. 8,102,184 issued on Jan. 24, 2012 to Sherry, et al, discloses a test fixture for electrically testing a device by forming a plurality of temporary mechanical and electrical connections between the terminals of the device under test (DUT) and the contact pads on a load board. The test fixture has a replaceable membrane that includes vias, each of which is associated with a terminal on the DUT and a contact pad on the load board. In some cases, each via has an electrically conducting wall for conducting current between the terminal and the contact pad. In some cases, each via includes a spring that provides mechanical resisting force to the terminal when the DUT is engaged with the test fixture. The proposed test fixture has a ribbon conductor that may have controlled impedance in any or all of the arms or strands and/or in the base. This controlled impedance may match that of adjacent electrical components, which may reduce reflected losses and may therefore improve the electrical performance of the conductor. Furthermore, the flexible or membrane circuit on top of the fixture is designed to provide, among other things, an interface with the DUT inside a cylinder for reducing electromagnetic interference and crosstalk.

U.S. Pat. No. 7,279,907 issued on Oct. 9, 2007 to Phoon, et al, discloses a method of testing for power and ground continuity of a semiconductor device having input and output (IO) pins and at least a pair of power and ground pins to identify the power and ground pins of the device. A victim pin is selected from the IO pins of the device for each pair of power and ground pins, and an aggressor pin for each victim pin is selected from the remaining IO pins. The aggressor pins are toggled between a high state and a low state. The level of switching noise on each victim pin is measured, and the measured levels of switching noise are compared with predetermined data to determine power and ground continuity of the device.

The method is performed when a semiconductor device to be tested, referred to as the device under test (DUT), is inserted into the test socket of a conventional load board. To minimize the incidence of reflections, which could potentially obscure the effects of switching noise on the victim pin signal, the victim and aggressor pins may be terminated with a terminating resistor having a resistance that matches a trace impedance of the load board on which the semiconductor device is tested. For example, the victim and aggressor pins are terminated with a 51-ohm terminating resistor when the board trace impedance is 51 ohms. Board trace impedance can be measured with the help of a Time Domain Reflectometry Scope or modeled by performing signal integrity simulation using HyperLynx software, which is available from Mentor Graphics Corporation (Wilsonville, Oreg.). Alternatively, the load board may be impedance-controlled by design. In other words, the board is designed to eliminate or reduce reflectance.

Thus, U.S. Pat. No. 5,290,193 issued on Mar. 1, 1994 to Goff, et al, discloses a high-density land grid array test socket that comprises a leadless component contact socket assembly and a fixture. The contact socket assembly can be assembled with a variety of contact terminal end configurations and adapted for a desired mode of circuit board interface. The dielectric on the interior of the base opening and the top opening can be formed of various insulative or dielectric materials or coatings such as polytetrafluoroethylene, nylon, FR4, or the like. Creating a transmission line environment for high-speed and fast rise-time signals enhances signal integrity. The thickness and/or composition of the dielectric in the cavity can be controlled to obtain desired impedance and/or crosstalk-limiting characteristics. While a first contact terminal receptacle is configured with the dielectric cavity for high-speed signal transmission, an adjacent cavity is configured without the dielectric to act as a ground/return. A space between the compliant ground/power bus bar and the row of signal-carrying contacts can be adjusted to obtain the desired impedance and/or crosstalk-limiting characteristic. This compliant ground/power bus bar provides a ground reference plane or a power plane that will carry current from the IC chip carrier/multichip module substrate to and from the printed circuit board.

U.S. Pat. No. 6,203,329 issued on Mar. 20, 2001 to Johnson, et al, discloses an impedance-controlled interconnection device for interconnecting a number of first terminals to a number of second terminals. The interconnection device includes a conductive housing and a number of contacts that are insulated from the conductive housing. This configuration may provide shielding to the number of contacts from outside sources of electromagnetic interference. Further, a number of conductive ribs may be provided between adjacent contacts, thereby shielding the contacts from crosstalk interference between adjacent contacts. Finally, the impedance of each contact in the interconnection device may be controlled to provide a stable bandpass, and may be programmable to match, or correct for, the input impedance of a corresponding device.

US Patent Application Publication No. 20040135594 published on Jul. 15, 2004 (inventors: Beaman, et al) discloses a compliant interposer assembly for wafer test and “burn-in” operations. The interposer accommodates variations in contact height, contact location, and contact materials and is in direct contact in the interface between the contact surface of the IC under test and the fan-out wiring surface of the test equipment. Each layer of the interposer that is to be in contact with the IC contacts and with the fan-out contacts has a comparable pattern of holes for each end region of each interconnect conductor member. The interconnect conductor members, in turn, send signals from each IC contact through one of the holes in the pattern in the IC interposer layer that is adjacent to the IC, the signals then pass through a bend in the movement area of the frame, and then pass through a corresponding hole in the pattern in the interposer layer adjacent to the fan-out. Compliant capability is thus built into the interposer contact layers for adaptability at each interface. Many interconnection systems use a one-to-one arrangement of signal and ground connections to approximate a controlled impedance interface. Such an approach reduces the effective number of signal connections that can be used on an IC device. The ability to have coaxial conductors provides a superior means of controlling impedance as well as reducing the coupled noise between signal conductors without reducing the effective number of signal connections that can be used on an IC device.

Nevertheless, all known impedance-matching devices and crosstalk-eliminating devices are relatively expensive to manufacture and are complicated in design.

### BRIEF DESCRIPTION OF THE DRAWINGS

FIG. 1 is an exploded perspective view of the test socket of the present invention.

FIG. 2 is a sectional view through the test socket of the present invention in the assembled state.

### SUMMARY OF THE INVENTION

The invention relates to a coaxial impedance-matched test socket for testing electrical and electronic devices, e.g., ICs. The socket comprises a probe holder that holds a plurality of pogo pins positioned in accordance with the arrangement of lead contacts of a specific IC. The probe holder is sandwiched between an upper probe retainer and a lower probe retainer. The IC to be tested is held in a guide plate, which is provided with guide holes for the ends of the lead contacts of the test circuit in order to maintain them in contact with the upper tips of the pogo pins, while the lower probe retainer is supported by a test board. The latter is connected to a tester and comprises a number of contact pads connected to respective measurement instruments for measuring the electrical signals obtained during testing of the IC.

A unique feature of the tester of the invention is the structure of the test socket body, which is similar to a system of redistributed coaxial cable inserts wherein the core of each insert comprises a pogo pin, the metal layer, e.g., a copper layer that surrounds the pogo pin functions as a shielding element of the core, and an air gap and an insulation filling between the pogo pin and the shielding metal part function as an insulator. For higher system efficiency in matching impedances between the input (pogo pins) and output (test object), the isolation fillings, which are placed between the outer surfaces of the control pogo pins and the inner surfaces of the metal layers, are made from a dielectric material of low dielectric permittivity. It is understood that this feature is especially essential for those pogo pins that transmit high-frequency signals, e.g., several GHz, or higher. By selecting specific dielectric materials with the required dielectric parameters, full matching can be provided.

### DETAILED DESCRIPTION OF THE INVENTION

In general, when the manufacturing process of a semiconductor chip, such as an IC, or the like, is completed, the chip is tested with regard to its electrical performance, quality of electrical contacts, etc. When a semiconductor device is to be tested, a test socket is placed between the lead contacts of the integrated circuit and the terminals of the measurement device. Current flows from the test terminals of the test device (printed circuit board) into the lead terminals of the semiconductor chip through the test socket, and signals from the lead terminals are analyzed to determine IC performance and semiconductor chip abnormality.

The problem associated with the through-hole fixture arrangement is the possible bending of or damage to the test pins extending up and through the load board, thus negatively affecting the test results. To avoid this problem, a receptacle can be positioned between the fixture and the load board to protect the test pins extending through the load board. The result of incorporating a receptacle requires the length of the test pins in the fixture to be increased, which creates a problem for testing high-speed integrated circuits. Incorporation of a spring probe that has a short travel length addresses this problem. However, with short travel springs, the spring life is short, therefore requiring constant replacement. In addition, the use of spring probes in the fixture can create an impedance problem for the transfer of the test signal from the ball grid array to the load board.

On the other hand, the test sockets for the FHST are made from insulative materials with high or low dielectric permittivity and cannot prevent contactors crosstalk because the wavelength becomes comparable to the length of the contactors, whereby the contactors behave as antennas and propagate radiofrequency.

The test socket of the present invention solves both the impedance and crosstalk problems at the same time. Apart from this, the proposed FHST socket design makes manufacturing of the test sockets less expensive as compared to traditional CNC machining by using printed circuit board technology.

More specifically, the impedance is matched by equalizing load impedance and source impedance. Ideally, source and load impedances should be purely resistive. In a special case, reflectionless matching is the same as maximum power-transfer matching. In other words, in measurement, there should be no reflection of the measurement signal at a point of contact. This can be expressed as follows:

Z_{load}=Z_{probe}=Z_{source}

where Z_{probe} is the characteristic impedance of a probe (pogo pin).

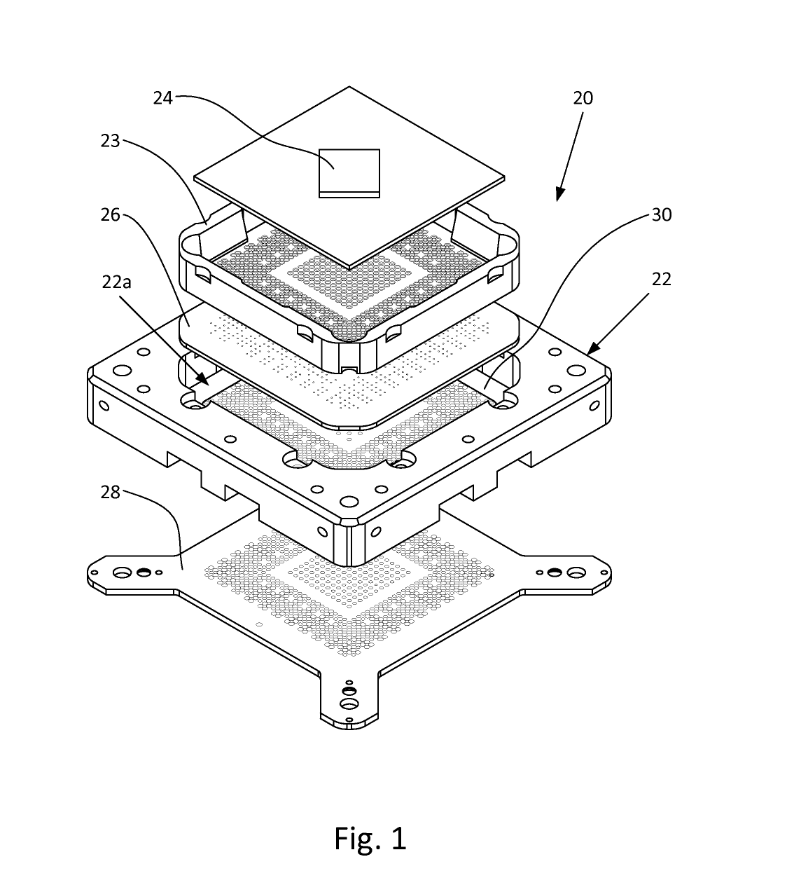

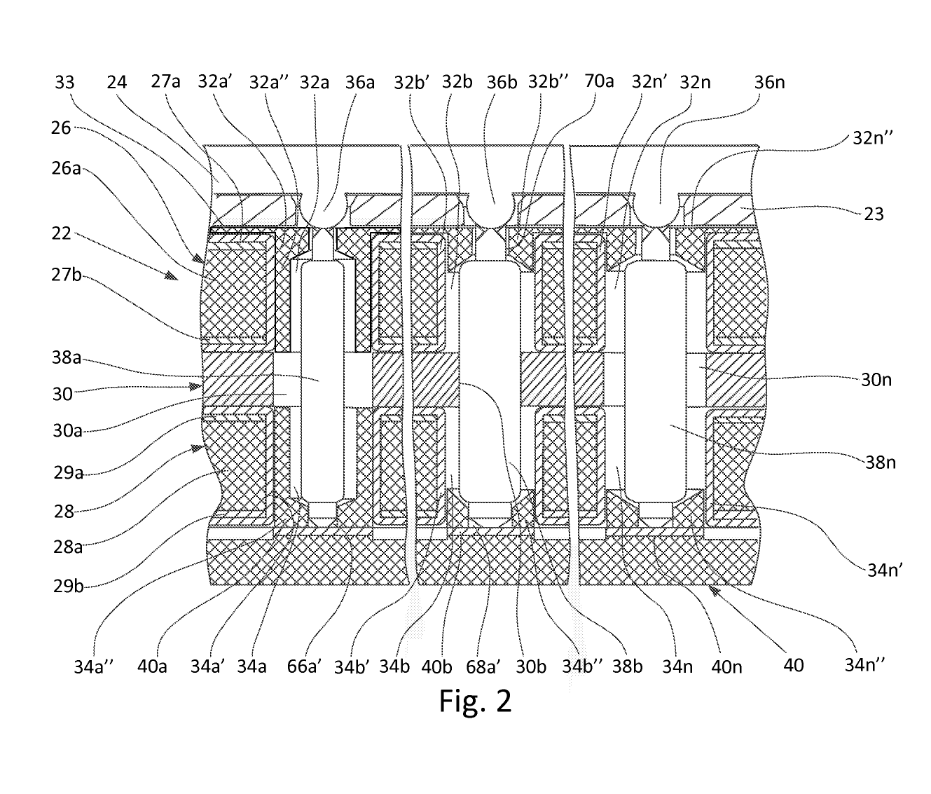

The test socket of the invention is shown in FIG. 1, which is an exploded perspective view of the test socket. It can be seen that the test socket, which in general is designated by reference numeral 20, comprises a test socket body 22, which is described below with reference to FIG. 2, and comprises a metallic probe holder 30 sandwiched between two laminated probe retainers, i.e., the upper probe retainer 26 and a lower probe retainer 28. FIG. 2 is a sectional view through the test socket of the present invention in the assembled state.

The test socket body 22 has a recess 22a inserted into the upper probe retainer 26 and the lower probe retainer 28. The upper probe retainer 26 comprises a double-sided laminated plate made from a dielectric material 26a coated on both sides with thin metal layers 27a and 27b and provided with through holes, only three of which are shown, i.e., holes 32a, 32b, and 32n. Similarly, the lower probe retainer 28 comprises a double-sided laminated plate made from a dielectric material core 28a coated on both sides with thin metal layers 29a and 29b and provided with through holes, only three of which are shown, i.e., 34a, 34b, and 34n.

The probe holder 30 is made from a conductive material, e.g., copper, aluminum, brass, etc. The probe holder 30 also has arrays of holes, only three of which, i.e., holes 30a, 302b, and 30n, are shown. The holes 30a, 302b, and 30n are aligned with the holes 32a, 32b, . . . 32n and 34a, 34b, . . . 34n of the upper and lower probe retainers 26a and 28a, respectively, and have the same diameters, except for the holes 30b, which are intended for insertion of the grounding pogo pins that must have electrical contact with the metal probe holder 30 of the grounding system.

Number and density distribution of all aligned holes depends on the arrangement of lead contacts of a specific Integrated circuit of the test object 24 that is to be tested. As mentioned above, both top and lower probe retainers 26 and 28, respectively, are double-sided laminated plates made from a dielectric material coated with thin metal layers.

A guide member 23 is provided between the test object 24 and the upper probe retainer 26 for aligning the lead contacts (not shown in FIG. 1) with the tips of the pogo pins, which are shown and described in connection with FIG. 2 below.

The inner surfaces of the holes 32a, 32b, and 32n of the upper probe retainer 26 are coated with metal layers 32a′, 32b′, 32n′, which may be applied, e.g., by electroplating. In the coating operation, the inner surfaces of the holes are covered with thin metal layers as well as the entire surface of the probe retainers, i.e., the flat metal-coated surfaces of the probe retainers 26 and 28.

The interiors of the metal-coated holes, in turn, are coated with hollow isolation inserts 32a″, 32b″, and 32n″. These inserts are formed by filling the aforementioned holes with a dielectric material such as PTFA (polytetrafluoroethylene), polyester, polyether, fluorocarbon, or the like, with subsequent formation of the holes for insertion of the pogo pins. The holes have dielectric inserts for two reasons: (1) if a hole ID has to be small due to small pitch, the use of the dielectric insert prevents pogo-pin contact with the metal layer inside the hole; and (2) use of a dielectric insert makes it possible to match impedance by selection of dielectric type, layer thickness, etc. In other words, the predetermined thickness and/or predetermined composition of the dielectric material of the isolation inserts can be used to obtain desired impedance and/or crosstalk-limiting characteristics.

The inner surfaces of the holes 34a, 34b, and 34n of the lower retainer 28 are coated with metal layers 34a′, 34b′, 34n′, which may be applied, e.g., by electroplating. The interiors of the metal-coated holes, in turn, are coated with hollow isolation inserts 34a″, 34b″, and 34n″. These inserts are formed by filling the aforementioned holes with a dielectric material such as PTFE (polytetrafluoroethylene), polyester, fluorocarbon, or the like, with subsequent formation of the holes for insertion of the pogo pins. Reference numeral 33 designates a continuous thin insulation layer which is formed from the dielectric material of the isolation inserts 32a″, 32b″, . . . 32n″ on the surface of the thin metal layers 27a simultaneously with the formation of the aforementioned inserts when the insulation material of the isolation inserts fills the holes 32a, 32b, . . . 32n. In other words, this thin insulation layer is continuous except for holes provided to ensure contact of the pogo pins with the respective lead contacts of the object being tested and may comprise a part of the isolation inserts formed in the holes of the upper and lower probe retainers 26 and 28, respectively.

Existence of such an insulation layer 33 provides an additional isolation of the solder bumps 36a, 36b, . . . 36n from accidental contact with metallic parts of the test socket body 22.

As seen in FIG. 2, contacts between lead terminals, hereinafter referred to as bumps, 36a, 36b, . . . 36n of the test object, i.e., the integrated-circuit chip 24 (FIG. 1), and a test board 40, which is connected to a measurement system (not shown), is carried out through spring probes 38a, 38b, . . . 38n. Such spring probes, which are also known and referred to as pogo pins, are standard devices available in various types and dimensions, and therefore their structure is beyond the scope of the present invention. For example, see, e.g., U.S. Pat. No. 8,062,078 granted to Asai, et. al, on Nov. 22, 2011.

Although only three pogo pins are shown in FIG. 2, there is a plurality of pogo pins of the depicted types. All of the selected pogo pins have point contacts at both ends, although this is not a compulsory condition.

The pogo pin 38n is a power pogo pin, which is intended for applying electrical power from respective contact pads, such as a contact pad 40n of the test board 40 to the respective bump 36n of the integrated circuit 24 (FIG. 1) to be tested.

The pogo pin 38b is a grounding pogo pin, which grounds the bump, such as the bump 36b (FIG. 2) of the integrated circuit 24 through the electrical contact with the metallic probe holder 30. The pogo pin 38b connects the respective bump 36b with a corresponding contact pad 40b of the test board 40.

The pogo pin 36a is a control pogo pin, which transmits a working signal (control signal) from the integrated circuit 24 to the test board 40 through its contact with the bump 36a and the respective contact pad 40a of the test board 40.

It is understood that the number of pogo pins corresponds to the number of the respective terminals, or bumps, on the integrated circuit 24.

It can be seen that the holes 30a, 30b, . . . 30n of the probe holder 30 have different diameters in order to accommodate pogo pins of different types, since, depending on their functions, these pins have different diameters. Thus, the hole 30b is smaller in diameter than the holes 30a and 30n, since the hole 30b provides an electrical contact of the grounding pogo pin 38b with the probe holder 30, which is grounded (see FIG. 2), while the power pogo pin 38n and the control pogo pin 38a are inserted into the holes 30n and 30a, the side walls of which are spaced from the side walls of the respective pogo pins.

It is understood that the contact pads 40a, 40b, . . . 40n are connected to respective measurement instruments (not shown) for measuring the electrical signals obtained during testing of the integrated circuit 24.

Thus, the uniqueness of the coaxial impedance-matched test socket 20 of the invention consists of power pogo pins, control pogo pins, and grounding pogo pins that are shielded from the environment by metal parts, except that the grounding pins have electrical contact with the shielding metal parts, wherein isolation of the pogo pins from the metal parts is provided either through an air gap along, such as air gap 32a, 34a, etc., or through an air gap in combination with dielectric material, such as isolation insert 32a″, 34a″, etc.

The upper probe retainer 26 and the lower probe retainer 28 comprise a standard double-sided laminated plate available, e.g., from McMaster-Carr®, USA.

The shielding metal layers 32a′, 32b′, 32n′, 34a′, 34b′, and 34n′ are layers applied, e.g., by a method selected from the group consisting of electroplating, electroless deposition, and deposition in vacuum.

Here we have a coaxial impedance-matched test socket having a socket body with a structure similar to a system of redistributed coaxial cable inserts wherein the core of each insert comprises a pogo pin, a metal layer, such as the metal layers 32a′, 34a′, etc., and the metal pin holder 30 comprise shielding elements of the core, and the isolation inserts 32a″, 34a″, etc., and air gaps between the pogo pins and the metal parts comprise insulators. For higher system efficiency in matching impedances between input (pogo pins) and output (test object 24), the isolation inserts 32a″ and 34a″, which are placed between the outer surfaces of the control pogo pins and the inner surface of the metal layers, are made from a dielectric material of high dielectric permeability. This feature is especially essential for those pogo pins that transmit high-frequency signals, e.g., several GHz, or higher. By selecting specific dielectric materials with the required dielectric parameters, full matching can be provided.

The applicants have found that construction of the test socket 20 provided with the above-described probe holder 30 and the system of redistributed and shielded pogo pins provides accurate testing with very high repeatability of measurement results.

By using formula (1), it is possible to define the probe diameter dᵢ of the control pogo pins 38a (FIG. 2), the diameter dₒ of the shielded holes 34a and 34b, and the type of insulator.

$${Z}_{0} = \frac{1}{2 π} \sqrt{\frac{{μ}_{0} {μ}_{r}}{{ɛ}_{0} {ɛ}_{r}}} ln ( \frac{d o}{d i} ) Ohms \qquad ( 1 )$$

where μᵣ is relative permeability, ∈ᵣ is relative dielectric constant, and Z₀=Θ is impedance of the probe. In order to satisfy the device under test ball pitch (<0.8 mm) and match, the impedance dielectric constant of insulator (∈ᵣ) should be minimal, or equal 1. Thus, the ideal insulator is an air gap 32a′, 34a″ (FIG. 2).

An additional advantageous feature of the impedance-matched test socket of the invention is the significantly simplified method of manufacturing this device. The method of manufacturing the impedance-matched test socket of this invention is a subject of pending U.S. patent application Ser. No. ______.

Although the invention is shown and described with reference to specific embodiments, it is understood that these embodiments should not be construed as limiting the areas of application of the invention and that any changes and modifications are possible, provided these changes and modifications do not depart from the scope of the attached patent claims. For example, the pogo pins may be of types different from those shown in the drawings. Also, these may be pogo pins with pointed tips, pogo pins with rounded tips, etc. The testers may be intended for testing objects other than integrated circuits, e.g., for testing multiple-contact electrical devices, electronic chips, CPU socket testers, etc.

1. A coaxial impedance-matched test socket for testing electrical circuits and elements of an electrical or electronic device with lead contacts, the test socket comprising:
an upper probe retainer, a lower probe retainer, and a metallic probe holder sandwiched between the upper probe retainer and the lower probe retainer, wherein both the upper probe retainer and the lower probe retainer comprise a double-sided laminated plate made from a dielectric material and covered from the top and bottom with a thin metal layer, and wherein the upper probe retainer, the lower probe retainer, and the probe holder have through holes that have inner walls and are aligned with each other;
a test board that supports the lower probe retainer and comprises contact pads for connection to respective measurement instruments for measuring the electrical signals obtained during testing of the object; and
pogo pins that are divided into pogo pins of a first type and pogo pins of a second type, wherein pogo pins of the first type have electrical contact with the inner walls of the holes of the probe retainer, and the pogo pins of the second type do not have electrical contact with the inner walls of the hole of the probe retainer.

2. The coaxial impedance-matched test socket of claim 1, wherein the electrical circuit comprises an integrated electrical circuit and wherein the pogo pins of the first type are grounding pogo pins for grounding the electrical or electronic device through the electrical contact with the inner walls of the holes in the metallic probe holder, which is grounded.

3. The coaxial impedance-matched test socket of claim 2, wherein the pogo pins of the second type are control pogo pins, which transmit a working signal from the electrical or electronic device to the respective contact pads of the test board, and power pogo pins, which apply electrical power from the respective contact pads of the test board to the respective electrical circuits and elements of the electrical or electronic device.

4. The coaxial impedance-matched test socket of claim 3, wherein an air gap is formed between the inner walls of the holes in the metallic probe holder and the outer surfaces of the pogo pins of the second type.

5. The coaxial impedance-matched test socket of claim 4, further comprising a shielding metal layer applied onto the inner surfaces of the holes of the upper probe retainer and of the lower probe retainer, the shielding metal layers comprising means for shielding the pogo pins from crosstalk and violation of transmitted signals.

6. The coaxial impedance-matched test socket of claim 5, further comprising isolation inserts formed between the shielding metal layers and the pogo pins.

7. The coaxial impedance-matched test socket of claim 6, wherein an air gap exists between the isolation inserts and the pogo pins of the first and second types.

8. The coaxial impedance-matched test socket of claim 5, further comprising a layer of an insulation material between the shielding metal layer and the guide member, said layer of insulation material having openings for contact of the pogo pins with the lead contacts of the electrical or electronic device.

9. The coaxial impedance-matched test socket of claim 6, further comprising a layer of an insulation material between the shielding metal layer and the guide member, said layer of insulation material having openings for contact of the pogo pins with the lead contacts of the electrical or electronic device.

10. The coaxial impedance-matched test socket of claim 9, wherein said layer of insulation material comprises a part of the insulation inserts formed in the holes of the upper and lower probe retainers.

11. The coaxial impedance-matched test socket of claim 1, wherein both the upper probe retainer and the lower probe retainer comprise a standard and commercially available double-sided laminated plate.

12. The coaxial impedance-matched test socket of claim 11, wherein the shielding metal layer is applied by a method selected from the group consisting of electroplating, electroless deposition, and deposition in vacuum.

13. The coaxial impedance-matched test socket of claim 5, wherein both the upper probe retainer and the lower probe retainer comprise a standard and commercially available double-sided laminated plate.

14. The coaxial impedance-matched test socket of claim 13, wherein the shielding metal layer is applied by a method selected from the group consisting of electroplating, electroless deposition, and deposition in vacuum.

15. The coaxial impedance-matched test socket of claim 6, wherein both the upper probe retainer and the lower probe retainer comprise a standard and commercially available double-sided laminated plate.

16. The coaxial impedance-matched test socket of claim 15, wherein the shielding metal layer is applied by a method selected from the group consisting of electroplating, electroless deposition, and deposition in vacuum.

17. The coaxial impedance-matched test socket of claim 6, wherein the isolation inserts are made from a dielectric material having a predetermined composition and thickness, and wherein the predetermined thickness and/or composition of the dielectric material of the isolation inserts can be used to obtain desired impedance and/or crosstalk-limiting characteristics.

18. The coaxial impedance-matched test socket of claim 7, wherein the isolation inserts are made from a dielectric material having a predetermined composition and thickness, and wherein the predetermined thickness and/or composition of the dielectric material of the isolation inserts can be used to obtain desired impedance and/or crosstalk-limiting characteristics.
